(19) United States
(12) Patent Application Publication
(10) Pub. No.: US 2025/0275479 A1
(43) Pub. Date: Aug. 28, 2025

(54) PIEZOELECTRIC ELEMENT, LIQUID EJECTION HEAD, AND PRINTER

(71) Applicant: SEIKO EPSON CORPORATION, Tokyo (JP)

(72) Inventors: Koji OHASHI, MATSUMOTO-SHI (JP); Yoshiki YANO, CHINO-SHI (JP); Yasuaki HAMADA, CHINO-SHI (JP); Tsukasa HITOMI, CHINO-SHI (JP); Masao NAKAYAMA, SHIOJIRI-SHI (JP)

(21) Appl. No.: 19/062,256

(22) Filed: Feb. 25, 2025

(30) Foreign Application Priority Data
Feb. 27, 2024 (JP) 2024-027243

(51) Int. Cl. H10N 30/853; B41J 2/14; H10N 30/00; H10N 30/097; H10N 30/87

(52) U.S. Cl. CPC H10N 30/8542; B41J 2/14233; B41J 2/1433; H10N 30/097; H10N 30/708; H10N 30/877; B41J 2002/14258

(57) ABSTRACT

A piezoelectric element includes a first electrode and a second electrode, a first piezoelectric layer provided between the first electrode and the second electrode, and a first orientation control layer provided between the first electrode and the first piezoelectric layer, wherein the first piezoelectric layer includes a plurality of layers each having a composite oxide having a perovskite-type structure containing potassium, sodium, and niobium, the layers contain crystal grains, a first layer of the plurality of layers is a layer provided directly on the first orientation control layer, a second layer of the plurality of layers is a layer different from the first layer, and an average grain size of the crystal grains contained in the first layer is larger than an average grain size of the crystal grains contained in the second layer.

The present application is based on, and claims priority from JP Application Serial Number 2024-027243, filed Feb. 27, 2024, the disclosure of which is hereby incorporated by reference herein in its entirety.

### BACKGROUND

### 1. Technical Field

The present disclosure relates to a piezoelectric element, a liquid ejection head, and a printer.

### 2. Related Art

A piezoelectric element used in a liquid ejection head or the like of an inkjet printer has a configuration in which a piezoelectric layer of a piezoelectric material having an electromechanical conversion function is sandwiched by two electrodes.

For example, JP-A-2014-36035 discloses a piezoelectric element including a KNN piezoelectric layer containing potassium, sodium, and niobium as main components.

JP-A-2014-36035 is an example of the related art.

In the above described piezoelectric element, it is desirable to reduce a leakage current.

### SUMMARY

A piezoelectric element according to an aspect of the present disclosure includes a first electrode and a second electrode, a first piezoelectric layer provided between the first electrode and the second electrode, and a first orientation control layer provided between the first electrode and the first piezoelectric layer, wherein the first piezoelectric layer includes a plurality of layers each having a composite oxide having a perovskite-type structure containing potassium, sodium, and niobium, the layers contains crystal grains, a first layer of the plurality of layers is a layer provided directly on the first orientation control layer, a second layer of the plurality of layers is a layer different from the first layer, and an average grain size of the crystal grains contained in the first layer is larger than an average grain size of the crystal grains contained in the second layer.

A liquid ejection head according to an aspect of the present disclosure includes the piezoelectric element, a channel formation substrate in which a pressure generation chamber having a volume changed by the piezoelectric element is formed, and a nozzle plate in which a nozzle hole that communicates with the pressure generation chamber is formed.

A printer according to an aspect of the present disclosure includes the liquid ejection head, a conveyance mechanism moving a recorded medium relative to the liquid ejection head, and a control unit controlling the liquid ejection head and the conveyance mechanism.

### BRIEF DESCRIPTION OF THE DRAWINGS

FIG. 1 is a cross-sectional view schematically showing a piezoelectric element according to an embodiment.

FIG. 2 shows crystal grains of the piezoelectric element according to the embodiment.

FIG. 3 is a cross-sectional view schematically showing a piezoelectric element according to a modified example of the embodiment.

FIG. 4 shows crystal grains of the piezoelectric element according to the modified example of the embodiment.

FIG. 5 is an exploded perspective view schematically showing a liquid ejection head according to the embodiment.

FIG. 6 is a plan view schematically showing the liquid ejection head according to the embodiment.

FIG. 7 is a cross-sectional view schematically showing the liquid ejection head according to the embodiment.

FIG. 8 is a perspective view schematically showing a printer according to the embodiment.

FIG. 9 is a table showing fabrication conditions of Examples 1 to 3 and Comparative Examples 1 and 2.

FIG. 10 is a table showing experimental results of Examples 1 to 3 and Comparative Examples 1 and 2.

### DESCRIPTION OF EMBODIMENTS

As below, preferred embodiments of the present disclosure will be described in detail using the drawings. The embodiments to be described below do not unduly limit the contents of the present disclosure described in the claims. In addition, not all configurations to be described below are necessarily essential component elements of the present disclosure.

### 1. Piezoelectric Element

### 1.1. Configuration

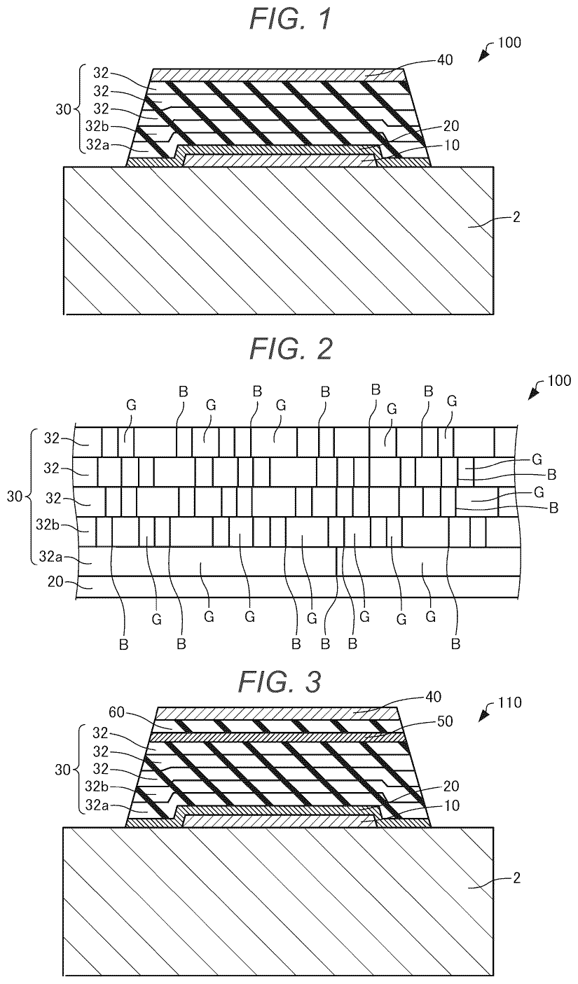

First, a piezoelectric element according to the embodiment will be described with reference to the drawings. FIG. 1 is a cross-sectional view schematically showing a piezoelectric element 100 according to the embodiment.

As shown in FIG. 1, the piezoelectric element 100 includes a first electrode 10, an orientation control layer 20, a piezoelectric layer 30, and a second electrode 40. The piezoelectric element 100 is provided on a base 2.

The base 2 is a flat plate formed using, for example, a semiconductor or an insulator. The base 2 may have a single layer structure or a layered structure in which a plurality of layers are stacked. The internal structure of the base 2 is not limited as long as an upper surface has a planar shape, and the base may have a structure with a space or the like formed therein.

The base 2 may include a vibrating plate that is deformed by an action of the piezoelectric layer 30. The vibrating plate includes, for example, a silicon oxide layer, a zirconium oxide layer, or a layered structure in which a zirconium oxide layer is provided on a silicon oxide layer.

The first electrode 10 is provided on the base 2. The first electrode 10 is provided between the base 2 and the orientation control layer 20. The first electrode 10 has, for example, a layer shape. The thickness of the first electrode 10 is, for example, from 5 nm to 300 nm, and preferably from 50 nm to 200 nm.

The first electrode 10 is, for example, a titanium layer, a platinum layer, or an iridium layer. The first electrode 10 may be a layered structure formed by sequential stacking of a titanium layer, a platinum layer, and an iridium layer from the base 2 side. The titanium layer increases, for example, adhesion between the base 2 and the platinum layer. The first electrode 10 is one electrode for applying a voltage to the piezoelectric layer 30.

The orientation control layer 20 is provided on the first electrode 10. The orientation control layer 20 is provided between the first electrode 10 and the piezoelectric layer 30. In the illustrated example, the orientation control layer 20 is further provided on the base 2. The thickness of the orientation control layer 20 is, for example, from 5 nm to 100 nm, and preferably from 10 nm to 50 nm. The permittivity of the orientation control layer 20 is lower than the permittivity of the piezoelectric layer 30.

The orientation control layer 20 includes, for example, a composite oxide having a perovskite-type structure containing bismuth (Bi), iron (Fe), titanium (Ti), and lead (Pb). The orientation control layer 20 is, for example, a bismuth ferrite lead titanate ((Bi, Pb) (Fe, Ti)O₃:BFTP) layer. The orientation control layer 20 may be a BFTP layer with an additive. The orientation control layer 20 controls the orientation of the piezoelectric layer 30.

The orientation control layer 20 is not limited to the BFTP layer as long as the layer can control the orientation of the piezoelectric layer 30, and may be a bismuth ferrite titanate (Bi (Fe, Ti)O₃:BFT) layer, a lanthanum nickel oxide (LaNiO₃:LNO) layer, a strontium ruthenate (SrRuO₃:SRO) layer, or a bismuth ferrite (BiFeO₃:BFO) layer. In addition, elements constituting the orientation control layer 20 may be diffused in the piezoelectric layer 30 and the first electrode 10.

The piezoelectric layer 30 is provided on the orientation control layer 20. The piezoelectric layer 30 is provided between the first electrode 10 and the second electrode 40. In the illustrated example, the piezoelectric layer 30 is provided between the orientation control layer 20 and the second electrode 40. The thickness of the piezoelectric layer 30 is, for example, from 100 nm to 3000 nm, and preferably from 200 nm to 2000 nm. The piezoelectric layer 30 is deformed by application of a voltage between the first electrode 10 and the second electrode 40.

For example, the piezoelectric layer 30 is preferentially oriented to the (100) plane. For example, the orientation control layer 20 preferentially orients the piezoelectric layer 30 to the (100) plane. The term “preferentially oriented to the (100) plane” refers to the (100) plane orientation rate at 70% or more. The term “(100) plane orientation rate” refers to a rate of crystal grains oriented to the (100) plane to all crystal grains constituting the piezoelectric layer 30. The (100) plane orientation rate in the piezoelectric layer 30 is, for example, from 70% to 100%, preferably 80% or more, and more preferably 90% or more. The piezoelectric layer 30 may include crystal grains oriented to the (110) plane and crystal grains oriented to the (111) plane.

The orientation rate of the piezoelectric layer 30 is measured by, for example, electron backscatter diffraction (EBSD) or X-ray diffraction (XRD).

The piezoelectric layer 30 includes a plurality of crystal layers 32. The piezoelectric layer 30 is formed by, for example, the plurality of crystal layers 32. The plurality of crystal layers 32 are stacked. The number of the plurality of the crystal layers 32 is, for example, from 2 to 30, and preferably from 3 to 20. In the illustrated example, five crystal layers 32 are provided. The thickness of the crystal layer 32 is, for example, from 10 nm to 200 nm, and preferably from 30 nm to 150 nm.

The crystal layer 32 is a layer containing a composite oxide having a perovskite-type structure containing potassium (K), sodium (Na), and niobium (Nb). The crystal layer 32 is, for example, a potassium sodium niobate ((K, Na)NbO₃:KNN) layer. The crystal layer 32 may be a KNN layer with an additive. The additive includes, for example, lithium (Li), manganese (Mn), copper (Cu), and oxides thereof. The content of the additive in the crystal layer 32 is, for example, 10 mol % or less, and preferably 5 mol % or less. The additive may be unevenly distributed in grain boundaries of the crystal layers 32.

A first crystal layer 32a of the plurality of crystal layers 32 is a layer provided directly on the orientation control layer 20. The first crystal layer 32a is in contact with the orientation control layer 20. The first crystal layer 32a is the first crystal layer 32 of the plurality of stacked crystal layers 32.

A second crystal layer 32b of the plurality of crystal layers 32 is a layer different from the first crystal layer 32a. In the illustrated example, the second crystal layer 32b is provided directly on the first crystal layer 32a. The second crystal layer 32b is in contact with the first crystal layer 32a. The first crystal layer 32a is provided between the orientation control layer 20 and the second crystal layer 32b. The second crystal layer 32b is the second crystal layer 32 of the plurality of stacked crystal layers 32.

The second electrode 40 is provided on the piezoelectric layer 30. Although not illustrated, the second electrode 40 may be further provided on the side surface of the piezoelectric layer 30, the side surface of the orientation control layer 20, and the base 2 as long as the second electrode is electrically isolated from the first electrode 10. The second electrode 40 has, for example, a layer shape. The thickness of the second electrode 40 is, for example, from 5 nm to 300 nm, and preferably from 50 nm to 200 nm.

The second electrode 40 is, for example, a platinum layer, a titanium layer, or an iridium layer. The second electrode 40 may be formed by stacking of a plurality of layers exemplified above. The second electrode 40 is another electrode for applying a voltage to the piezoelectric layer 30.

### 1.2. Crystal Grains of Crystal Layers

FIG. 2 shows crystal grains of the crystal layers 32. For convenience, members other than the orientation control layer 20 and the piezoelectric layer 30 are not shown in FIG. 2.

As shown in FIG. 2, the crystal layer 32 contains a plurality of crystal grains G. The crystal grains G are, for example, columnar crystals. The average grain size of the crystal grains G contained in the first crystal layer 32a is larger than the average grain size of the crystal grains G contained in the second crystal layer 32b. The average grain size of the crystal grains G contained in the first crystal layer 32a is, for example, from 10 μm to 50 μm. The average grain size of the crystal grains G contained in the second crystal layer 32b is, for example, from 0.1 μm to 0.5 μm.

The average grain size of the crystal grains G contained in the third crystal layer 32, the average grain size of the crystal grains G contained in the fourth crystal layer 32, and the average grain size of the crystal grains G contained in the fifth crystal layer 32 of the plurality of crystal layers 32 are, for example, from 0.1 μm to 0.5 μm. The average grain size of the crystal grains G contained in the first crystal layer 32a is larger than the average grain size of the crystal grains G contained in the third crystal layer 32, the average grain size of the crystal grains G contained in the fourth crystal layer 32, and the average grain size of the crystal grains G contained in the fifth crystal layer 32.

As the method of obtaining the average grain size of the crystal grains G in the crystal layer 32, the surface of the crystal layer 32 is observed with a scanning electron microscope (SEM), and five crystal grains G within an image are randomly selected. Then, the maximum span is measured with respect to each of the selected crystal grains G. The term “maximum span” refers to a length of the longest line segment that can be drawn inside the defined contour of the crystal grain G without protruding from the contour. The average of the obtained maximum spans of the respective crystal grains G is used as the average grain size of the crystal grains G in the crystal layer 32.

In the illustrated example, grain boundaries B of the crystal grains G of the first crystal layer 32a and the grain boundaries B of the crystal grains G of the second crystal layer 32b are not continuous. In a plan view, for example, the grain boundary B of the crystal grains G of the first crystal layer 32a and the grain boundary B of the crystal grains G of the second crystal layer 32b do not overlap with each other. The grain boundary B defines, for example, the contour of the crystal grain G.

### 1.3. Functions and Effects

The piezoelectric element 100 includes the first electrode 10 and the second electrode 40, the piezoelectric layer 30 as a first piezoelectric layer provided between the first electrode 10 and the second electrode 40, and the orientation control layer 20 as a first orientation control layer provided between the first electrode 10 and the piezoelectric layer 30. The piezoelectric layer 30 includes the plurality of crystal layers 32 each having the composite oxide having the perovskite-type structure containing potassium, sodium, and niobium. The crystal layer 32 includes the crystal grains G. The first crystal layer 32a of the plurality of crystal layers 32 is the layer provided directly on the orientation control layer 20, and the second crystal layer 32b of the plurality of crystal layers 32 is the layer different from the first crystal layer 32a. The average grain size of the crystal grains G contained in the first crystal layer 32a is larger than the average grain size of the crystal grains G contained in the second crystal layer 32b.

Accordingly, in the piezoelectric element 100, as shown in “Examples and Comparative Examples”, which will be described later, a leakage current can be reduced. In the piezoelectric element 100, for example, since the average grain size of the crystal grains G contained in the first crystal layer 32a is larger than the average grain size of the crystal grains G contained in the second crystal layer 32b, the grain boundaries B of the crystal grains G contained in the first crystal layer 32a and the grain boundaries B of the crystal grains G contained in the second crystal layer 32b may be made discontinuous. Thereby, leak paths between the first electrode 10 and the second electrode 40 can be reduced. As a result, the leakage current can be reduced. The potassium and sodium not forming the KNN layer may be accumulated at the grain boundaries B and, when the grain boundaries B are continuous in the thickness direction of the crystal layer, leak paths are formed.

In the piezoelectric element 100, the average grain size of the crystal grains G contained in the first crystal layer 32a is 10 μm or more, and the average grain size of the crystal grains G contained in the second crystal layer 32b is 0.5 μm or less. Accordingly, in the piezoelectric element 100, as shown in “Examples and Comparative Examples” to be described later, the leakage current can be reduced.

In the piezoelectric element 100, the (100) plane orientation rate in the piezoelectric layer 30 is 90% or more. Therefore, in the piezoelectric element 100, a good piezoelectric property can be provided.

### 2. Method of Manufacturing Piezoelectric Element

Next, a method of manufacturing the piezoelectric element 100 according to the embodiment will be described with reference to the drawings.

As shown in FIG. 1, the base 2 is prepared. Specifically, a silicon oxide layer is formed by thermal oxidation of a silicon substrate. Then, a zirconium layer is formed on the silicon oxide layer by sputtering or the like, and the zirconium layer is thermally oxidized and a zirconium oxide layer is formed. The base 2 can be prepared in the above described process.

Then, the first electrode 10 is formed on the base 2. The first electrode 10 is formed by, for example, sputtering or vacuum deposition. Then, the first electrode 10 is patterned by, for example, photolithography and etching.

Then, the orientation control layer 20 is formed on the first electrode 10 and the base 2. The orientation control layer 20 is formed by, for example, a chemical solution deposition (CSD) method such as a sol-gel method or metal organic deposition (MOD).

Specifically, first, a BFTP precursor solution is prepared by dissolution or dispersion of a metal complex containing bismuth, a metal complex containing iron, a metal complex containing titanium, and a metal complex containing lead in an organic solvent. Then, the BFTP precursor solution is applied onto the first electrode 10 by spin coating and a BFTP precursor layer is formed. Then, the BFTP precursor layer is heated, for example, at 130° C. to 250° C. and dried for a certain period of time, and the dried BFTP precursor layer is further heated, for example, at 300° C. to 450° C. and held for a certain period of time to be degreased. Then, the degreased BFTP precursor layer is crystallized by firing at, for example, 550° C. to 800° C. The firing is performed in an oxygen atmosphere. As described above, the orientation control layer 20 including the BFTP layer can be formed.

Then, the piezoelectric layer 30 is formed on the orientation control layer 20. The piezoelectric layer 30 is formed by, for example, a CSD method.

Specifically, first, for example, a KNN precursor solution is prepared by dissolution or dispersion of a metal complex containing potassium, a metal complex containing sodium, and a metal complex containing niobium in an organic solvent.

For example, the metal complex containing potassium includes potassium 2-ethylhexanoate. For example, the metal complex containing sodium includes sodium 2-ethylhexanoate. For example, the metal complex containing niobium includes niobium 2-ethylhexanoate.

For example, the organic solvent includes 2-ethylhexanoic acid, decane, and a mixed solvent thereof. When a mixed solvent of ethylhexanoic acid and decane is used as the organic solvent, the volume ratio of the 2-ethylhexanoic acid to the entire organic solvent is, for example, from 0.30 to 0.50, and preferably from 0.40 to 0.45.

Then, the prepared KNN precursor solution is applied onto the orientation control layer 20 by spin coating or the like and a KNN precursor layer is formed. Then, the KNN precursor layer is heated, for example, at 130° C. to 250° C. and dried for a certain period of time, and the dried KNN precursor layer is further heated, for example, at 300° C. to 450° C. and held for a certain period of time to be degreased. Then, the degreased KNN precursor layer is crystallized by firing. The firing temperature is, for example, from 600° C. to 800° C., preferably from 650° C. to 750° C., and more preferably from 675° C. to 725° C. The temperature rise rate in the firing is, for example, from 1° C./sec to 20° C./sec, preferably from 5° C./sec to 15° C./sec, and more preferably from 8° C./sec to 12° C./sec. The firing is performed in an oxygen atmosphere.

In the above described manner, the first crystal layer 32a including the KNN layer can be formed on the orientation control layer 20.

Then, the second crystal layer 32b including the KNN layer is formed on the first crystal layer 32a. The firing temperature for forming the second crystal layer 32b is, for example, from 450° C. to 650° C., preferably from 500° C. to 600° C., and more preferably from 525° C. to 575° C. The firing temperature for forming the second crystal layer 32b is lower than the firing temperature for forming the first crystal layer 32a. Thereby, the average grain size of the crystal grains G contained in the second crystal layer 32b can be made smaller than the average grain size of the crystal grains G contained in the first crystal layer 32a.

The method of forming the second crystal layer 32b is the same as, for example, the method of forming the first crystal layer 32a except for the above described firing temperature.

Then, a series of steps from the application of the KNN precursor solution for forming the second crystal layer 32b to the firing of the KNN precursor layer is repeated a plurality of times. Thereby, the piezoelectric layer 30 including the plurality of crystal layers 32 can be formed.

In the process of forming the crystal layer 32, a heating device used for drying and degreasing the KNN precursor layer is, for example, a hot plate. A heating device used for firing the KNN precursor layer is an infrared lamp annealing (rapid thermal annealing: RTA) device.

Then, the second electrode 40 is formed on the piezoelectric layer 30. The second electrode 40 is formed by, for example, sputtering or vacuum deposition. Then, the second electrode 40, the piezoelectric layer 30, and the orientation control layer 20 are patterned by, for example, photolithography and etching. The second electrode 40, the piezoelectric layer 30, and the orientation control layer 20 may be patterned in separate steps.

The piezoelectric element 100 can be manufactured in the above described process.

In the above description, the example in which the firing temperature for forming the second crystal layer 32b is set to be lower than the firing temperature for forming the first crystal layer 32a, and thereby, the average grain size of the crystal grains G contained in the second crystal layer 32b is made smaller than the average grain size of the crystal grains G contained in the first crystal layer 32a is explained. For example, the temperature rise rate of the firing for forming the second crystal layer 32b is set to be lower than the temperature rise rate of the firing for forming the first crystal layer 32a, and thereby, the average grain size of the crystal grains G contained in the second crystal layer 32b may be made smaller than the average grain size of the crystal grains G contained in the first crystal layer 32a.

In this case, the temperature rise rate of firing for forming the second crystal layer 32b is, for example, from 0.1° C./sec to 1.0° C./sec, preferably from 0.2° C./sec to 0.8° C./sec, and more preferably from 0.3° C./sec to 0.7° C./sec. The firing temperature for forming the second crystal layer 32b may be the same as the firing temperature for forming the first crystal layer 32a.

As described in above, the method of manufacturing the piezoelectric element 100, the first crystal layer 32a is a layer fired at a first temperature rise rate and a first temperature, the second crystal layer 32b is a layer fired at a second temperature rise rate and a second temperature, and the firing for forming the first crystal layer 32a and the firing for forming the second crystal layer 32b include at least one of the following first condition and second condition.

First condition: the first temperature rise rate is higher than the second temperature rise rate.

Second condition: the first temperature is higher than the second temperature.

The method of manufacturing the piezoelectric element 100 includes at least one of the first condition and the second condition, and thereby, the average grain size of the crystal grains G contained in the first crystal layer 32a can be made larger than the average grain size of the crystal grains G contained in the second crystal layer 32b.

### 3. Modified Example of Piezoelectric Element

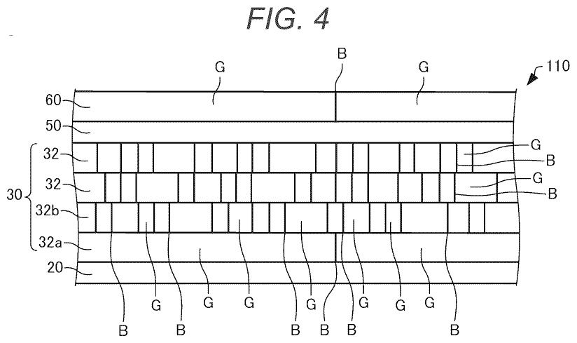

Next, a piezoelectric element 110 according to a modified example of the embodiment will be described with reference to the drawings. FIG. 3 is a cross-sectional view schematically showing the piezoelectric element 110 according to the modified example of the embodiment. FIG. 4 shows the crystal grains G of the piezoelectric element 110 according to the modified example of the embodiment.

As below, in the piezoelectric element 110 according to the modified example of the embodiment, the members having the same functions as the component members of the piezoelectric element 100 according to the embodiment described above, have the same signs and the detailed description thereof will be omitted.

As shown in FIGS. 3 and 4, the piezoelectric element 110 differs from the above described piezoelectric element 100 in that an orientation control layer 50 and a piezoelectric layer 60 are provided. For convenience, illustration of the members other than the orientation control layers 20 and 50 and the piezoelectric layers 30 and 60 is omitted in FIG. 4.

The orientation control layer 50 is provided on the piezoelectric layer 30. The orientation control layer 50 is provided between the piezoelectric layer 30 and the piezoelectric layer 60. For example, the thickness of the orientation control layer 50 is the same as the thickness of the orientation control layer 20. For example, the material of the orientation control layer 50 is the same as the material of the orientation control layer 20. For example, the method of forming the orientation control layer 50 is the same as the method of forming the orientation control layer 20. The orientation control layer 50 controls the orientation of the piezoelectric layer 60.

The piezoelectric layer 60 is provided on the orientation control layer 50. The piezoelectric layer 60 is provided between the orientation control layer 50 and the second electrode 40. The piezoelectric layer 60 is provided directly on the orientation control layer 50. The piezoelectric layer 60 is in contact with the orientation control layer 50. The thickness of the piezoelectric layer 60 is, for example, from 10 nm to 200 nm, and preferably from 30 nm to 150 nm. The thickness of the piezoelectric layer 60 may be the same as the thickness of the crystal layer 32. For example, the material of the piezoelectric layer 60 is the same as the material of the piezoelectric layer 30. For example, the method of forming the piezoelectric layer 60 is the same as the method of forming the first crystal layer 32a of the piezoelectric layer 30. Although not illustrated, the piezoelectric layer 60 may include a plurality of crystal layers.

As shown in FIG. 4, the piezoelectric layer 60 includes the crystal grains G. The average grain size of the crystal grains G contained in the piezoelectric layer 60 is larger than the average grain size of the crystal grains G contained in the second crystal layer 32b. Further, for example, the average grain size of the crystal grains G contained in the piezoelectric layer 60 is larger than the average grain size of the crystal grains G contained in the third crystal layer 32 and the average grain size of the crystal grains G contained in the fourth crystal layer 32 of the plurality of crystal layers 32. In the illustrated example, the piezoelectric layer 30 has four crystal layers 32. The average grain size of the crystal grains G contained in the piezoelectric layer 60 is, for example, from 10 μm to 50 μm.

The piezoelectric element 110 includes the piezoelectric layer 60 as a second piezoelectric layer provided between the piezoelectric layer 30 and the second electrode 40, and the orientation control layer 50 as a second orientation control layer provided between the piezoelectric layer 30 and the piezoelectric layer 60, and the piezoelectric layer 60 has a composite oxide having a perovskite-type structure containing potassium, sodium, and niobium. Therefore, in the piezoelectric element 110, the orientation control layer 50 can control the orientation of the piezoelectric layer 60.

In the piezoelectric element 110, the piezoelectric layer 60 includes the crystal grains G and is provided directly on the orientation control layer 50, and the average grain size of the crystal grains G contained in the piezoelectric layer 60 is larger than the average grain size of the crystal grains G contained in the second crystal layer 32b. As described above, in the piezoelectric element 110, the orientation control layer 50 is provided, and thereby, the average grain size of the crystal grains G contained in the piezoelectric layer 60 can be made larger than the average grain size of the crystal grains G contained in the second crystal layer 32b.

Although not illustrated, for example, a plurality of the orientation control layers 50 may be provided, and the orientation control layer 50 may be provided between the adjacent crystal layers 32. That is, the orientation control layer 50 and the crystal layer 32 may be alternately stacked.

### 4. Liquid Ejection Head

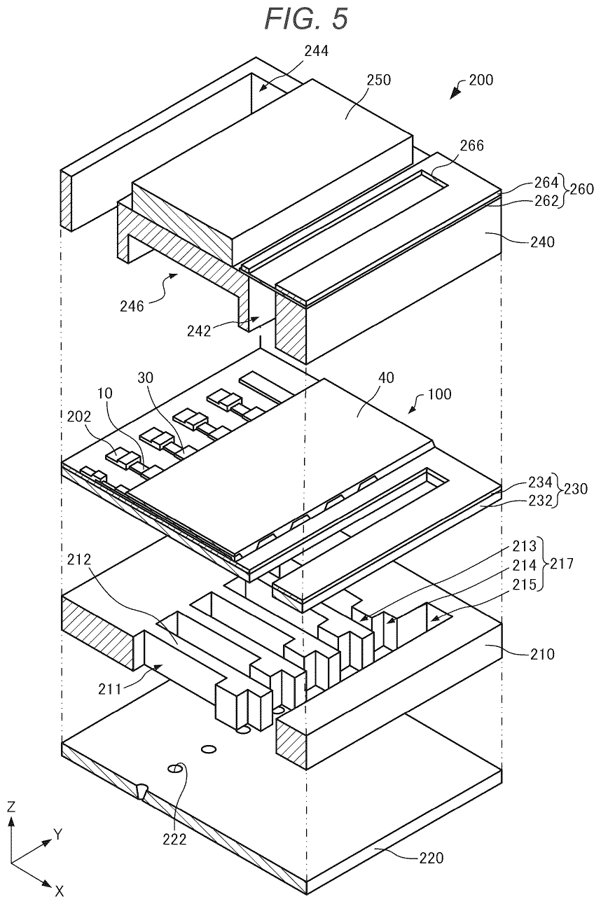

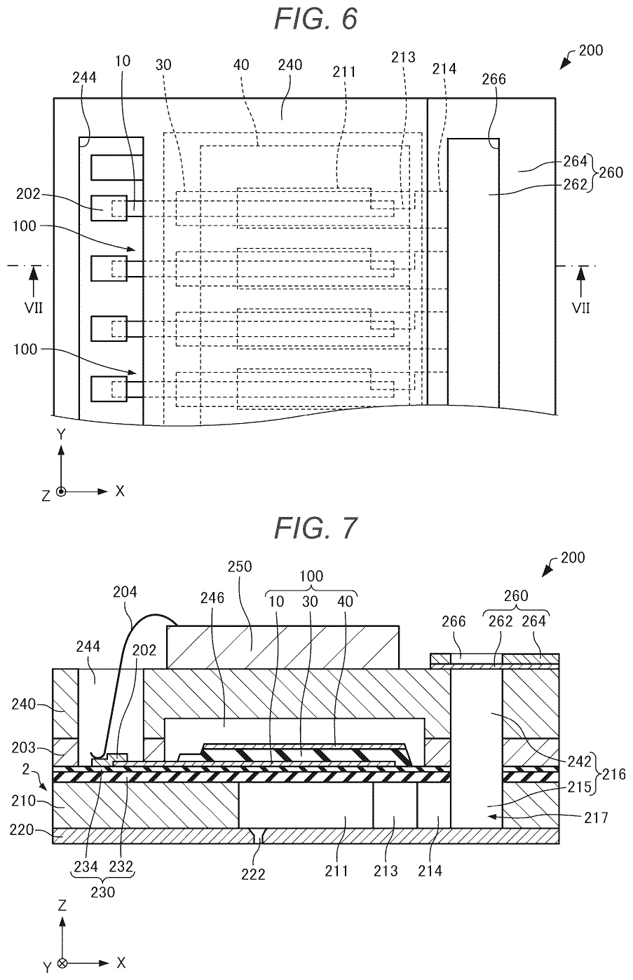

Next, a liquid ejection head according to the embodiment will be described with reference to the drawings. FIG. 5 is an exploded perspective view schematically showing a liquid ejection head 200 according to the embodiment. FIG. 6 is a plan view schematically showing the liquid ejection head 200 according to the embodiment. FIG. 7 is a cross-sectional view cut along line VII-VII in FIG. 6, schematically showing the liquid ejection head 200 according to the embodiment. FIGS. 5 to 7 show an X-axis, a Y-axis, and a Z-axis as three axes orthogonal to one another. In FIGS. 5 and 7, the piezoelectric element 100 is shown in a simplified manner.

As shown in FIGS. 5 to 7, for example, the liquid ejection head 200 includes the base 2, the piezoelectric elements 100, a nozzle plate 220, a protective substrate 240, a circuit board 250, and a compliance substrate 260. The base 2 includes a channel formation substrate 210 and a vibrating plate 230. For convenience, in FIG. 6, the illustration of the circuit board 250 is omitted.

The channel formation substrate 210 is, for example, a silicon substrate. Pressure generation chambers 211 are formed in the channel formation substrate 210. The pressure generation chambers 211 are divided by a plurality of partition walls 212. The volume of the pressure generation chamber 211 is changed by the piezoelectric element 100.

First communication paths 213 and second communication paths 214 are formed in end portions in a +X-axis direction of the pressure generation chambers 211 in the channel formation substrate 210. The first communication path 213 is formed to have an opening area smaller by reduction of the end portion in the +X-axis direction of the pressure generation chamber 211 from a Y-axis direction. For example, the size of the second communication path 214 in the Y-axis direction is the same as the size of the pressure generation chamber 211 in the Y-axis direction. A third communication path 215 communicating with the plurality of second communication paths 214 is formed in the +X-axis direction of the second communication paths 214. The third communication path 215 forms a part of a manifold 216. The manifold 216 serves as a common liquid chamber for the pressure generation chambers 211. Thus, a supply channel 217 including the first communication paths 213, the second communication paths 214, and the third communication path 215, and the pressure generation chambers 211 are formed in the channel formation substrate 210. The supply channel 217 communicates with the pressure generation chambers 211 and supplies a liquid to the pressure generation chambers 211.

The nozzle plate 220 is provided on one surface of the channel formation substrate 210. For example, the material of the nozzle plate 220 is steel use stainless (SUS). The nozzle plate 220 is bonded to the channel formation substrate 210 by, for example, an adhesive or a heat-welded film. A plurality of nozzle holes 222 are formed in the nozzle plate 220 along the Y-axis. The nozzle hole 222 communicates with the pressure generation chamber 211 and ejects the liquid.

The vibrating plate 230 is provided on the other surface of the channel formation substrate 210. The vibrating plate 230 includes, for example, a silicon oxide layer 232 provided on the channel formation substrate 210 and a zirconium oxide layer 234 provided on the silicon oxide layer 232.

For example, the piezoelectric element 100 is provided on the vibrating plate 230. The plurality of piezoelectric elements 100 are provided. The number of the piezoelectric elements 100 is not particularly limited. For convenience, in FIG. 7, the illustration of the orientation control layer 20 is omitted.

In the liquid ejection head 200, the vibrating plate 230 and the first electrode 10 are displaced by the deformation of the piezoelectric layer 30 having electromechanical conversion characteristics. That is, in the liquid ejection head 200, the vibrating plate 230 and the first electrode 10 substantially function as a vibrating plate. The vibrating plate 230 may be omitted, and only the first electrode 10 may function as the vibrating plate. When the first electrode 10 is directly provided on the channel formation substrate 210, it is preferable to protect the first electrode 10 by an insulating protective film or the like so that the first electrode 10 is not brought into contact with the liquid.

The first electrode 10 is formed as an individual electrode independent for each pressure generation chamber 211. The size of the first electrode 10 in the Y-axis direction is smaller than the size of the pressure generation chamber 211 in the Y-axis direction. The size of the first electrode 10 in the X-axis direction is larger than the size of the pressure generation chamber 211 in the X-axis direction. In the X-axis direction, both end portions of the first electrode 10 are located outside both end portions of the pressure generation chamber 211. A lead electrode 202 is coupled to the end portion of the first electrode 10 in the-X-axis direction.

For example, the size of the piezoelectric layer 30 in the Y-axis direction is larger than the size of the first electrode 10 in the Y-axis direction. For example, the size of the piezoelectric layer 30 in the X-axis direction is larger than the size of the pressure generation chamber 211 in the X-axis direction. For example, an end portion of the piezoelectric layer 30 in the +X-axis direction is located outside the end portion of the first electrode 10 in the +X-axis direction. The end portion of the first electrode 10 in the +X-axis direction is covered by the piezoelectric layer 30. On the other hand, for example, an end portion of the piezoelectric layer 30 in the −X-axis direction is located inside the end portion of the first electrode 10 in the −X-axis direction. The end portion of the first electrode 10 in the-X-axis direction is not covered by the piezoelectric layer 30.

For example, the second electrode 40 is provided continuously on the piezoelectric layer 30 and the vibrating plate 230. The second electrode 40 is formed as a common electrode to the plurality of piezoelectric elements 100.

The protective substrate 240 is bonded to the channel formation substrate 210 by an adhesive 203. A through hole 242 is formed in the protective substrate 240. In the illustrated example, the through hole 242 penetrates the protective substrate 240 in a Z-axis direction and communicates with the third communication path 215. The through hole 242 and the third communication path 215 form the manifold 216 serving as the common liquid chamber for the respective pressure generation chambers 211. Further, in the protective substrate 240, a through hole 244 that penetrates the protective substrate 240 in the Z-axis direction is formed. An end portion of the lead electrode 202 is located in the through hole 244.

An opening portion 246 is formed in the protective substrate 240. The opening portion 246 is a space to prevent inhibition of driving of the piezoelectric elements 100. The opening portion 246 may be sealed or not.

The circuit board 250 is provided on the protective substrate 240. The circuit board 250 includes a semiconductor integrated circuit (IC) for driving the piezoelectric elements 100. The circuit board 250 and the lead electrode 202 are electrically coupled via a coupling wire 204.

The compliance substrate 260 is provided on the protective substrate 240. The compliance substrate 260 includes a sealing layer 262 provided on the protective substrate 240 and a fixing plate 264 provided on the sealing layer 262. The sealing layer 262 is a layer for sealing the manifold 216. For example, the sealing layer 262 has flexibility. A through hole 266 is formed in the fixing plate 264. The through hole 266 penetrates the fixing plate 264 in the Z-axis direction. The through hole 266 is provided in a position overlapping with the manifold 216 as seen from the Z-axis direction.

### 5. Printer

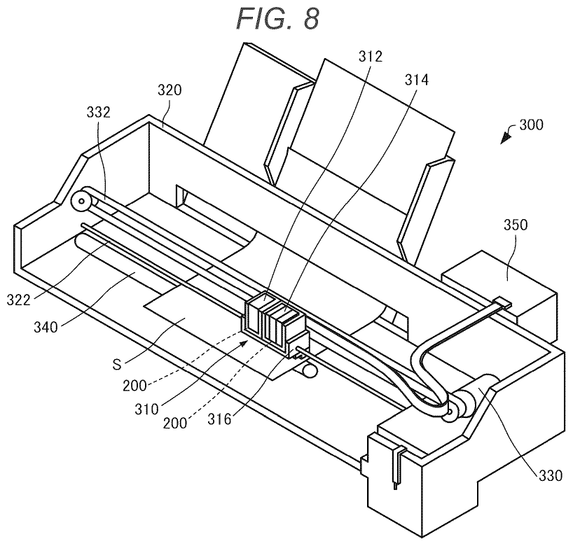

Next, a printer according to the embodiment will be described with reference to the drawing. FIG. 8 is a perspective view schematically showing a printer 300 according to the embodiment.

The printer 300 is an inkjet printer. As shown in FIG. 8, the printer 300 includes a head unit 310. For example, the head unit 310 includes the liquid ejection heads 200. The number of liquid ejection heads 200 is not particularly limited. In the head unit 310, cartridges 312 and 314 forming a supply unit are detachably provided. A carriage 316 on which the head unit 310 is mounted is provided on a carriage shaft 322 attached to an apparatus main body 320 to be movable in axial directions, and ejects a liquid supplied from a liquid supply unit.

Here, the liquid refers to any material of a substance in a liquid phase and includes materials in liquid states such as sols and gels. Further, the liquid includes not only the liquid as a state of a substance, but also a liquid with particles of a solid functional material such as pigments or metal particles dissolved, dispersed, or mixed in a solvent. Representative examples of the liquid include inks and liquid crystal emulsions. The term ink includes various types of liquid compositions such as general water-based ink, oil-based ink, gel ink, and hot-melt ink.

In the printer 300, a driving force of a drive motor 330 is transmitted to the carriage 316 via a plurality of gears (not shown) and a timing belt 332, and thereby, the carriage 316 with the head unit 310 mounted thereon is moved along the carriage shaft 322. Meanwhile, the apparatus main body 320 is provided with a conveyance roller 340 as a conveyance mechanism for moving a sheet S as a recorded medium such as paper relative to the liquid ejection head 200. The conveyance mechanism that conveys the sheet S is not limited to the conveyance roller, but may be a belt, a drum, or the like.

The printer 300 includes a printer controller 350 as a control unit that controls the liquid ejection head 200 and the conveyance roller 340. The printer controller 350 is electrically coupled to the circuit board 250 of the liquid ejection head 200. The printer controller 350 includes, for example, a RAM (Random Access Memory) that temporarily stores various types of data, a ROM (Read Only Memory) that stores control programs and the like, a CPU (Central Processing Unit), and a drive signal generation circuit that generates drive signals to be supplied to the liquid ejection head 200.

The piezoelectric element 100 can be used in a wide range of applications, not limited to a liquid ejection head and a printer. For example, the piezoelectric element 100 is preferably used as a piezoelectric actuator of an ultrasonic motor, a vibrating dust removal device, a piezoelectric transformer, a piezoelectric speaker, a piezoelectric pump, and a pressure-electricity conversion device. Further, for example, the piezoelectric element 100 is preferably used as a piezoelectric sensor element of an ultrasonic detector, an angular velocity sensor, an acceleration sensor, a vibration sensor, a tilt sensor, a pressure sensor, a collision sensor, a human sensor, an infrared sensor, a terahertz sensor, a heat detection sensor, a pyroelectric sensor, and a piezoelectric sensor. Furthermore, the piezoelectric element 100 is preferably used as a ferroelectric element of a ferroelectric memory (FeRAM), a ferroelectric transistor (FeFET), a ferroelectric calculation circuit (FeLogic), and a ferroelectric capacitor. In addition, the piezoelectric element 100 is preferably used as a voltage-controlled optical element of a wavelength converter, an optical waveguide, an optical path modulator, a refractive index control element, and an electronic shutter mechanism.

### 6. Examples and Comparative Examples

### 6.1. Fabrications of Samples

### 6.1.1. Example 1

A surface of a single-crystal silicon substrate was thermally oxidized and an SiO₂ layer having a thickness of 1460 nm was formed. Then, a Zr film having a thickness of 400 nm was formed by a direct current (DC) sputtering method, and a ZrO₂ layer was formed by heat treatment at 850° C.

Then, as a first electrode, a Ti layer having a thickness of 20 nm, a Pt layer having a thickness of 80 nm, and an Ir layer having a thickness of 5 nm were formed on the ZrO₂ layer by a DC sputtering method.

Then, a BFTP precursor solution was prepared so as to have a molar ratio of Bi:Pb:Fe:Ti=110:10:50:50. Then, the prepared BFTP precursor solution was applied onto the Ir layer and the ZrO₂ layer by spin coating, dried at 180° C. for 3 minutes, degreased at 380° C. for 3 minutes, and fired at 650° C. for 3 minutes. The firing was performed in an oxygen atmosphere. In the above described manner, a BFTP layer having a thickness of 20 nm was formed.

Next, simple solutions containing potassium 2-ethylhexanoate, sodium 2-ethylhexanoate, and niobium 2-ethylhexanoate were respectively synthesized. These simple solutions were blended in a molar ratio of K:Na:Nb=50:50:100, MnO at 0.2 wt % was added, and a KNN precursor solution was obtained.

Then, the prepared KNN precursor solution was applied onto the BFTP layer by spin coating, dried at 180° C. for 3 minutes, degreased at 380° C. for 3 minutes, and fired at 700° C. for 3 minutes. The temperature rise rate of the firing was set to 10° C./sec. The firing was performed by lamp annealing in an oxygen atmosphere. In the above described manner, a first KNN layer having a thickness of 80 nm was formed.

Then, the KNN precursor solution was applied onto the first KNN layer by spin coating, dried and degreased in the same manner as that for the first KNN layer, and then, fired at 550° C. for 3 minutes. The temperature rise rate of the firing was set to 10° C./sec. The firing was performed by lamp annealing in an oxygen atmosphere. In the above described manner, a second KNN layer having a thickness of 80 nm was formed.

Then, third, fourth, and fifth KNN layers were formed on the same conditions as those for the second KNN layer.

In the above described manner, a piezoelectric layer including the five KNN layers having a thickness of 400 nm was formed.

Next, a Pt layer having a thickness of 100 nm was formed on the piezoelectric layer by a DC sputtering method. Then, the Pt layer was patterned by photolithography and etching and a circular second electrode having a diameter of 500 μm in a plan view was formed.

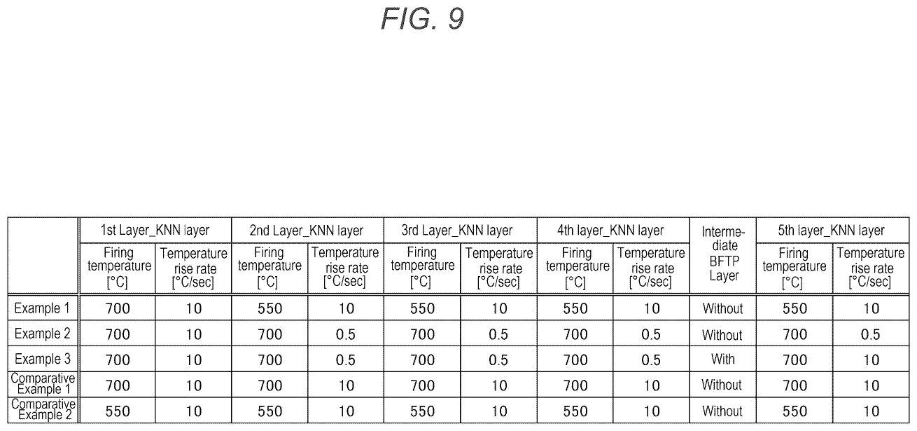

In the above described manner, a piezoelectric element of Example 1 was formed. FIG. 9 is a table showing manufacturing conditions of Examples 1 to 3 and Comparative Examples 1 and 2.

### 6.1.2. Example 2

A piezoelectric element of Example 2 was formed in the same manner as in Example 1 except that the firing temperature of the second to fifth KNN layers was set to 700° C. and the temperature rise rate was set to 0.5° C./sec. The piezoelectric elements of Examples 1 and 2 correspond to the piezoelectric element 100 shown in FIGS. 1 and 2.

### 6.1.3. Example 3

The firing temperature of the second to fourth KNN layers was set to 700° C., and the temperature rise rate was set to 0.5° C./sec. Then, a BFTP layer was formed on the fourth KNN layer on the same conditions as in Example 1. Then, the fifth KNN layer was formed on the BFTP layer on the same conditions as those of the first KNN layer of Example 1.

Except for the above described conditions, a piezoelectric element of Example 3 was formed in the same manner as in Example 1. The piezoelectric element of Example 3 corresponds to the piezoelectric element 110 shown in FIGS. 3 and 4.

### 6.1.4. Comparative Example 1

A piezoelectric element of Comparative Example 1 was formed in the same manner as in Example 1 except that the firing temperature of the second to fifth KNN layers was set to 700° C. That is, in Comparative Example 1, the firing temperatures were set to 700° C. and the temperature rise rates were set to 10° C./sec for all the first to fifth KNN layers.

### 6.1.5. Comparative Example 2

A piezoelectric element of Comparative Example 2 was formed in the same manner as in Example 1 except that the firing temperature of the first KNN layer was set to 550° C. That is, in Comparative Example 2, the firing temperatures were set to 550° C. and the temperature rise rates were set to 10° C./sec for all the first to fifth KNN layers.

### 6.2. Experimental Conditions

### 6.2.1 Average Particle Diameters

The surfaces of the respective KNN layers were observed and the average particle sizes were measured. Specifically, five crystal grains within a SEM image were randomly selected, the maximum span was measured for each of the selected crystal grains, and the average was defined as the average grain size of the KNN layer. As a SEM, “JSM-7800F” manufactured by JEOL was used.

### 6.2.2. Orientation Rates

In the piezoelectric layer, the (100) plane orientation rate, the (110) plane orientation rate, and the (111) plane orientation rate were measured. The orientation rate was measured by EBSD. For the EBSD, “Aztec HKL Advanced Nordlys-Nano” manufactured by Oxford Instruments was used. The measurement region was set to 50 μm×50 μm.

### 6.2.3. Leakage Current

The leakage current of the piezoelectric element was measured by evaluation of the IV characteristics. As a device, “4140B” manufactured by Keisight was used. The leakage current was measured when a drive voltage of 5V was applied to the first electrode.

The evaluation criteria of the leakage current are as follows.
A: less than 1×10⁻⁷ A/cm²
B: 1×10⁻⁷ A/cm² or more and less than 1×10⁻⁵ A/cm²
C: 1×10⁻⁵ A/cm² or more and less than 1×10⁻⁴ A/cm²
D: 1×10⁻⁴ A/cm² or more, or short circuit

### 6.3. Experimental Results

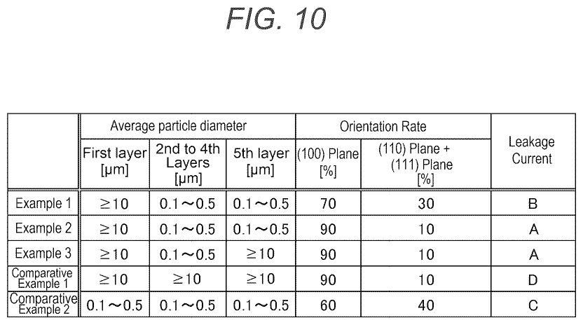

FIG. 10 is a table showing experimental results of Examples 1 to 3 and Comparative Examples 1 and 2.

As shown in FIG. 10, in Example 1, the firing temperatures of the second to fifth KNN layers were set to be lower than that for the first KNN layer, and thereby, the average grain sizes of the crystal grains contained in the second to fifth KNN layers were smaller than that of the first KNN layer.

In Example 2, the temperature rise rates of the firing of the second to fifth KNN layers were set to be lower than that for the first KNN layer, and thereby, the average grain sizes of the crystal grains contained in the second to fifth KNN layers were smaller than that of the first KNN layer.

In Example 3, the temperature rise rates of the firing of the second to fourth KNN layers were set to be smaller than that for the first KNN layer, and thereby, the average grain sizes of the crystal grains contained in the second to fourth KNN layers were smaller than that of the first KNN layer. The average grain size of the crystal grains contained in the fifth KNN layer was substantially the same as that of the first KNN layer.

On the other hand, in Comparative Examples 1 and 2, since the firing temperatures and the temperature rise rates of the firing were not changed in the respective KNN layers, the average grain sizes of the crystal grains in the respective KNN layers were substantially the same.

In Examples 2 and 3, the firing temperatures were higher than those in Example 1, and thereby, the (100) plane orientation rates were higher. With the higher (100) plane orientation rate, the piezoelectric property can be improved. However, it is considered that, in Example 3, the BFTP layer as a low permittivity layer is formed between the fourth KNN layer and the fifth KNN layer, and thereby, the piezoelectric property is lower than that in Example 2.

In Examples 1 to 3, the leakage currents were smaller than those of Comparative Examples 1 and 2 in which the average grain sizes of the crystal grains were substantially the same in the respective KNN layers. In particular, in Examples 2 and 3, the leakage currents were smaller than that in Example 1. Comparative Example 1 was short-circuited.

The above described embodiments and modified examples are just examples, and the present disclosure is not limited thereto. For example, the respective embodiments and the respective modified examples may be combined as appropriate.

The present disclosure includes substantially the same configurations as the configurations described in the embodiments, such as a configuration having the same function, method, and result and a configuration having the same object and effect. The present disclosure includes a configuration in which a non-essential portion of the configuration described in the embodiment is replaced. Further, the present disclosure includes a configuration that exerts the same function and effect or a configuration that can achieve the same purpose as the configurations described in the embodiments. Furthermore, the present disclosure includes a configuration with the addition of a known technique to the configuration described in the embodiments.

The following contents are derived from the embodiment and modifications described above.

A piezoelectric element according to an aspect includes a first electrode and a second electrode, a first piezoelectric layer provided between the first electrode and the second electrode, and a first orientation control layer provided between the first electrode and the first piezoelectric layer, wherein the first piezoelectric layer includes a plurality of layers each having a composite oxide having a perovskite-type structure containing potassium, sodium, and niobium, the layers contain crystal grains, a first layer of the plurality of layers is a layer provided directly on the first orientation control layer, a second layer of the plurality of layers is a layer different from the first layer, and an average grain size of the crystal grains contained in the first layer is larger than an average grain size of the crystal grains contained in the second layer.

According to the piezoelectric element, a leakage current can be reduced.

In the piezoelectric element according to the aspect, the average grain size of the crystal grains contained in the first layer may be 10 μm or more, and the average grain size of the crystal grains contained in the second layer may be 0.5 μm or less.

According to the piezoelectric element, the leakage current can be reduced.

In the piezoelectric element according to the aspect, a (100) plane orientation rate in the first piezoelectric layer may be 90% or more.

According to the piezoelectric element, a good piezoelectric property can be provided.

In the piezoelectric element according to the aspect, the first layer may be a layer fired at a first temperature rise rate and a first temperature, the second layer may be a layer fired at a second temperature rise rate and a second temperature, and at least one of conditions that the first temperature rise rate is higher than the second temperature rise rate and the first temperature is higher than the second temperature may be satisfied.

According to the piezoelectric element, the average grain size of the crystal grains contained in the first layer can be made larger than the average grain size of the crystal grains contained in the second layer.

The piezoelectric element according to the aspect, further includes a second piezoelectric layer provided between the first piezoelectric layer and the second electrode, and a second orientation control layer provided between the first piezoelectric layer and the second piezoelectric layer, wherein the second piezoelectric layer may include a composite oxide having a perovskite-type structure containing potassium, sodium, and niobium.

According to the piezoelectric element, the orientation of the second piezoelectric layer can be controlled by the second orientation control layer.

In the piezoelectric element according to the aspect, the second piezoelectric layer may contain crystal grains and may be provided directly on the second orientation control layer, and an average grain size of the crystal grains contained in the second piezoelectric layer may be larger than the average grain size of the crystal grains contained in the second layer.

According to the piezoelectric element, the second orientation control layer is provided, and thereby, the average grain size of the crystal grains contained in the second piezoelectric layer can be made larger than the average grain size of the crystal grains contained in the second layer.

A liquid ejection head according to an aspect includes the piezoelectric element according to the aspect, a channel formation substrate in which a pressure generation chamber having a volume changed by the piezoelectric element is formed, and a nozzle plate in which a nozzle hole that communicates with the pressure generation chamber is formed.

A printer according to an aspect includes the liquid ejection head according to the aspect, a conveyance mechanism moving a recorded medium relative to the liquid ejection head, and a control unit controlling the liquid ejection head and the conveyance mechanism.

What is claimed is:

1. A piezoelectric element comprising:
a first electrode and a second electrode;
a first piezoelectric layer provided between the first electrode and the second electrode; and
a first orientation control layer provided between the first electrode and the first piezoelectric layer, wherein
the first piezoelectric layer includes a plurality of layers each having a composite oxide having a perovskite-type structure containing potassium, sodium, and niobium,
the layers contain crystal grains,
a first layer of the plurality of layers is a layer provided directly on the first orientation control layer,
a second layer of the plurality of layers is a layer different from the first layer, and
an average grain size of the crystal grains contained in the first layer is larger than an average grain size of the crystal grains contained in the second layer.

2. The piezoelectric element according to claim 1, wherein
the average grain size of the crystal grains contained in the first layer is 10 μm or more, and
the average grain size of the crystal grains contained in the second layer is 0.5 μm or less.

3. The piezoelectric element according to claim 1, wherein
a (100) plane orientation rate in the first piezoelectric layer is 90% or more.

4. The piezoelectric element according to claim 1, wherein
the first layer is a layer fired at a first temperature rise rate and a first temperature,
the second layer is a layer fired at a second temperature rise rate and a second temperature, and
at least one of conditions that the first temperature rise rate is higher than the second temperature rise rate and the first temperature is higher than the second temperature is satisfied.

5. The piezoelectric element according to claim 1, further comprising:
a second piezoelectric layer provided between the first piezoelectric layer and the second electrode; and
a second orientation control layer provided between the first piezoelectric layer and the second piezoelectric layer, wherein
the second piezoelectric layer includes a composite oxide having a perovskite-type structure containing potassium, sodium, and niobium.

6. The piezoelectric element according to claim 5, wherein
the second piezoelectric layer contains crystal grains and is provided directly on the second orientation control layer, and an average grain size of the crystal grains contained in the second piezoelectric layer is larger than the average grain size of the crystal grains contained in the second layer.

7. A liquid ejection head comprising:
the piezoelectric element according to claim 1;
a channel formation substrate in which a pressure generation chamber having a volume changed by the piezoelectric element is formed; and
a nozzle plate in which hole that communicates with the pressure generation chamber is formed.

8. A printer comprising:
the liquid ejection head according to claim 7;
a conveyance mechanism moving a recorded medium relative to the liquid ejection head; and
a control unit controlling the liquid ejection head and the conveyance mechanism.
